(19) United States
(12) Patent Application Publication
(10) Pub. No.: US 2014/0102499 A1
(43) Pub. Date: Apr. 17, 2014

(54) THERMOELECTRIC POWER GENERATION DEVICE AND ELECTRIC POWER GENERATION METHOD

(71) Applicant: PANASONIC CORPORATION, Osaka (JP)

(72) Inventors: Kohei TAKAHASHI, Osaka (JP); Tsutomu KANNO, Kyoto (JP); Akihiro SAKAI, Nara (JP); Hiromasa TAMAKI, Osaka (JP); Yuka YAMADA, Nara (JP)

(73) Assignee: PANASONIC CORPORATION, Osaka (JP)

(21) Appl. No.: 14/141,203

(22) Filed: Dec. 26, 2013

Related U.S. Application Data
(63) Continuation of application No. PCT/JP2013/001854, filed on Mar. 19, 2013.

(30) Foreign Application Priority Data
Apr. 27, 2012 (JP) 2012-103393

(51) Int. Cl. H01L 35/32

(52) U.S. Cl. CPC H01L 35/32
USPC 136/201; 136/209

(57) ABSTRACT

A thermoelectric power generation device includes: a that vessel has an inlet through which a first fluid is introduced and an outlet through which the first fluid is discharged; a tubular thermoelectric element that has a flow-through path through which a second fluid having a temperature different from that of the first fluid flows; a pair of flow path members each penetrating a wall of the vessel while being electrically insulated from the vessel; and lead wires. The flow path members are connected to ends of the thermoelectric element. The flow path members each have a conductive portion extending from a connecting portion between the flow path member and the thermoelectric element to the outside of the vessel. The lead wires each are connected to the conductive portion in the outside of the vessel.

This is a continuation of International Application No. PCT/JP2013/001854, with an international filing date of Mar. 19, 2013, which claims the foreign priority of Japanese Patent Application No. 2012-103393, filed on Apr. 27, 2012, the entire contents of both of which are hereby incorporated by reference.

### BACKGROUND OF THE INVENTION

1. Field of the Invention

The present disclosure relates to a thermoelectric power generation device and an electric power generation method using the thermoelectric power generation device.

2. Description of Related Art

When a temperature difference occurs between both ends of a thermoelectric material, an electromotive force is generated in proportion to the temperature difference. This effect is known as the Seebeck effect in which thermal energy is converted into electrical energy. Thus, thermoelectric elements and thermoelectric power generation devices utilizing the Seebeck effect to generate electric power have been proposed.

For example, as a thermoelectric element, a tubular thermoelectric element, in which conical rings of Bi_{0.5}Sb_{1.5}Te₃ as a thermoelectric material and conical rings of Ni are alternately stacked and electrically connected with Sn—Bi solder paste, has been proposed (Nanotechnology Materials and Devices Conference (NMDC), 2011, IEEE Proceedings, pp. 56-60). A thermoelectric power generation device 100 using a tubular thermoelectric element, as shown in FIG. 9, has also been proposed (WO 2012/014366 A1). In the thermoelectric power generation device 100, a tubular thermoelectric element 110 is immersed in cold fluid (water) 130 filled in a vessel 120, and hot fluid (hot water) 140 is allowed to flow through an internal through hole of the thermoelectric element 110. The hot fluid 140 is circulated by a pump 150. The pump 150 and the thermoelectric element 110 are connected by two silicone tubes 160. A first electrode 111 and a second electrode 112 at the ends of the thermoelectric element 110 are electrically connected to a load 180 via two electric wires 170. Electric power generated in the thermoelectric element 110 is transmitted to the outside of the thermoelectric element 110 through the first electrode 111 and the second electrode 112 and through the electric wires 170.

Even if a configuration as disclosed in WO 2012/014366 A1 is employed as a thermoelectric power generation device using a tubular thermoelectric element, there is still room for improvement in the electric power generation performance.

### SUMMARY OF THE INVENTION

The present disclosure has been made in view of the above circumstances, and one non-limiting and exemplary embodiment provides a thermoelectric power generation device with improved electric power generation performance.

Additional benefits and advantages of the disclosed embodiments will be apparent from the specification and Figures. The benefits and/or advantages may be individually provided by the various embodiments and features of the specification and drawings disclosure, and need not all be provided in order to obtain one or more of the same.

In one general aspect, the techniques disclosed here feature a thermoelectric power generation device, including: a vessel having an inlet through which a first fluid is introduced into the vessel and an outlet through which the first fluid is discharged from the vessel, the vessel being sealed to form an enclosed interior space therein; a tubular thermoelectric element having a flow-through path through which a second fluid having a temperature different from that of the first fluid flows, the thermoelectric element being disposed in the interior space of the vessel; a pair of flow path members each having a communication flow path therein, the pair of flow path members being connected to ends of the thermoelectric element so as to allow the flow-through path to communicate with an outside of the vessel through the communication flow paths; and lead wires. In this device, the pair of flow path members each penetrate a wall of the vessel while being electrically insulated from the vessel and each have a conductive portion extending from a connecting portion between the flow path member and the thermoelectric element to the outside of the vessel, and the lead wires are each connected to the conductive portion in the outside of the vessel.

The present disclosure can provide a thermoelectric power generation device having high electric power generation performance.

### BRIEF DESCRIPTION OF THE DRAWINGS

FIG. 1 is a cross-sectional view of a thermoelectric power generation device according to a first embodiment.

FIG. 2 is a cross-sectional view taken along the line V-V in FIG. 1.

FIG. 3 is a perspective view of a thermoelectric element according to the first embodiment.

FIG. 4 is an exploded perspective view of the thermoelectric element according to the first embodiment.

FIG. 5 is a cross-sectional view of a thermoelectric power generation device according to a second embodiment.

FIG. 6 is a graph showing the electric power generation performance of a thermoelectric power generation device according to Example 1.

FIG. 7 is a graph showing the electric power generation performance of a thermoelectric power generation device according to Example 2.

FIG. 8 is a graph showing the electric power generation performance of a thermoelectric power generation device according to Comparative Example.

FIG. 9 is a diagram showing a conventional thermoelectric power generation device.

### DETAILED DESCRIPTION

(Findings as a Basis for the Present Disclosure)

First, the findings as a basis for the present disclosure are described.

In the thermoelectric power generation device 100 described in WO 2012/014366 A1, the thermoelectric element 110 is merely immersed in the fluid filled in the vessel 120. Therefore, natural convection is dominant in the motion of the fluid in the vessel 120, and probably the flow velocity of the fluid is not high in the vicinity of the thermoelectric element 110. The top of the vessel 120 is open.

It may be possible to configure a thermoelectric power generation device in which a vessel is provided with an inlet for introducing a fluid thereinto and an outlet for discharging the fluid therefrom so as to flow the fluid in the vessel. The present inventors have found that a thermoelectric power generation device including a vessel whose top is covered with a lid, for example, to form an enclosed interior space can exhibit higher electric power generation performance than a thermoelectric power generation device including an open-top vessel as disclosed in WO 2012/014366 A1. The reason for this is probably as follows.

In the case of a thermoelectric power generation device including an open-top vessel, the amount of the fluid that can be supplied to the vessel is limited to prevent overflow of the fluid from the vessel. Therefore, it is difficult to increase the flow velocity of the fluid in the vicinity of the thermoelectric element. In addition, in the case of the thermoelectric power generation device including the open-top vessel, even if the capacity of the vessel is increased to increase the amount of the fluid that can be supplied to the vessel, it is still difficult to increase the flow velocity of the fluid in the vicinity of the thermoelectric element. In contrast, since the thermoelectric power generation device including the sealed vessel having an enclosed interior space has no such limitation, a greater amount of fluid can be supplied to the vessel so as to increase the flow velocity of the fluid in the vicinity of the thermoelectric element. As a result, the thermoelectric element is efficiently cooled or heated in the thermoelectric power generation device including the sealed vessel having an enclosed interior space, resulting in high electric power generation performance.

However, in the device including such a sealed vessel, it is troublesome to connect lead wires for transmitting electric power generated in the thermoelectric element to the outside of the element. Under these circumstances, the present inventors have found that the use of flow path members each having a conductive portion extending from the connecting portion between the flow path member and the thermoelectric element to the outside of the vessel facilitates the connection of lead wires for transmitting electricity derived from the electromotive force generated in the thermoelectric element to the outside. The present disclosure has been made based on these findings.

(Description of Aspects of the Present Disclosure)

According to a first aspect of the present disclosure, there is provided a thermoelectric power generation device, including: a vessel having an inlet through which a first fluid is introduced into the vessel and an outlet through which the first fluid is discharged from the vessel, the vessel being sealed to form an enclosed interior space therein; a tubular thermoelectric element having a flow-through path through which a second fluid having a temperature different from that of the first fluid flows, the thermoelectric element being disposed in the interior space of the vessel; a pair of flow path members each having a communication flow path therein, the pair of flow path members being connected to ends of the thermoelectric element so as to allow the flow-through path to communicate with an outside of the vessel through the communication flow paths; and lead wires, wherein the pair of flow path members each penetrate a wall of the vessel while being electrically insulated from the vessel and each have a conductive portion extending from a connecting portion between the flow path member and the thermoelectric element to the outside of the vessel, and the lead wires are each connected to the conductive portion in the outside of the vessel.

According to the first aspect, since the tubular thermoelectric element is disposed in the enclosed interior space of the vessel having the inlet through which the first fluid is introduced thereinto and the outlet through which the first fluid is discharged therefrom, the flow velocity of the first fluid in the vicinity of the thermoelectric element is increased. Therefore, the thermoelectric element can be cooled or heated efficiently. As a result, the electric power generation performance of the thermoelectric power generation device can be enhanced. In addition, since the lead wires are connected to the conductive portions extending from the connecting portion with the thermoelectric element in the outside of the vessel, electric power generated in the thermoelectric element disposed in the enclosed interior space of the vessel can easily be transmitted to the outside.

According to a second aspect of the present disclosure, there is provided the thermoelectric power generation device according to the first aspect, wherein the flow path members are formed of a conductive material, and the vessel is formed of an insulating material.

According to the second aspect, the vessel and the flow path members can be electrically insulated from each other with a simple configuration. In addition, since the flow path members are formed of a conductive material and the resistance of the conductive portions is relatively low, the electric power generation performance of the thermoelectric power generation device is enhanced.

According to a third aspect of the present disclosure, there is provided the thermoelectric power generation device according to the first aspect, wherein the conductive portion includes: a substrate made of an insulating material; and a conductive layer covering an outer surface of the substrate, and the vessel is formed of an insulating material.

According to the third aspect, the conductive portion can be formed only on a portion required to transmit the electric power generated in the thermoelectric element to the outside.

According to a fourth aspect of the present disclosure, there is provided the thermoelectric power generation device according to any one of the first to third aspects, wherein the conductive portion has an electrical resistance of 100 mΩ or less.

According to the fourth aspect, the electrical resistance of the conductive portions is relatively low, and the electric power generation performance of the thermoelectric power generation device is enhanced.

According to a fifth aspect of the present disclosure, there is provided a thermoelectric power generation device including: a vessel having an inlet through which a first fluid is introduced into the vessel and an outlet through which the first fluid is discharged from the vessel, the vessel being sealed to form an enclosed interior space therein; a plurality of tubular thermoelectric elements each having a flow-through path through which a second fluid having a temperature different from that of the first fluid flows, the thermoelectric elements being disposed in the interior space of the vessel; pairs of flow path members each having a communication flow path therein, each of the pairs of flow path members corresponding to one of the thermoelectric elements and being connected to ends of the thermoelectric element so as to allow the flow-through path to communicate with an outside of the vessel through the communication flow paths; and lead wires, wherein the flow path members each penetrate a wall of the vessel while being electrically insulated from the vessel and each have a conductive portion extending from a connecting portion between the flow path member and the thermoelectric element to the outside of the vessel, the lead wires are connected to the conductive portions in the outside of the vessel, and the thermoelectric elements are connected in series through the lead wires and the conductive portions.

According to the above-described fifth aspect, since the plurality of thermoelectric elements are connected in series, the electric power generation performance of the thermoelectric power generation device is enhanced.

According to a sixth aspect of the present disclosure, there is provided a method for generating electric power, including the steps of preparing the thermoelectric power generation device according to any one of the first to fifth aspects; introducing the first fluid into the vessel through the inlet and discharging the first fluid from the vessel through the outlet; causing the second fluid to flow in the flow-through path through the flow path members; and transmitting electric power generated in the thermoelectric element to the outside of the vessel through the flow path members and the lead wires.

According to the sixth aspect, an electric power generation method having the same effects as those of the first to fifth aspects can be provided.

### DESCRIPTION OF EMBODIMENTS OF THE PRESENT DISCLOSURE

Hereinafter, embodiments of the present disclosure will be described with reference to the drawings. The present disclosure is not limited to the following embodiments.

### First Embodiment

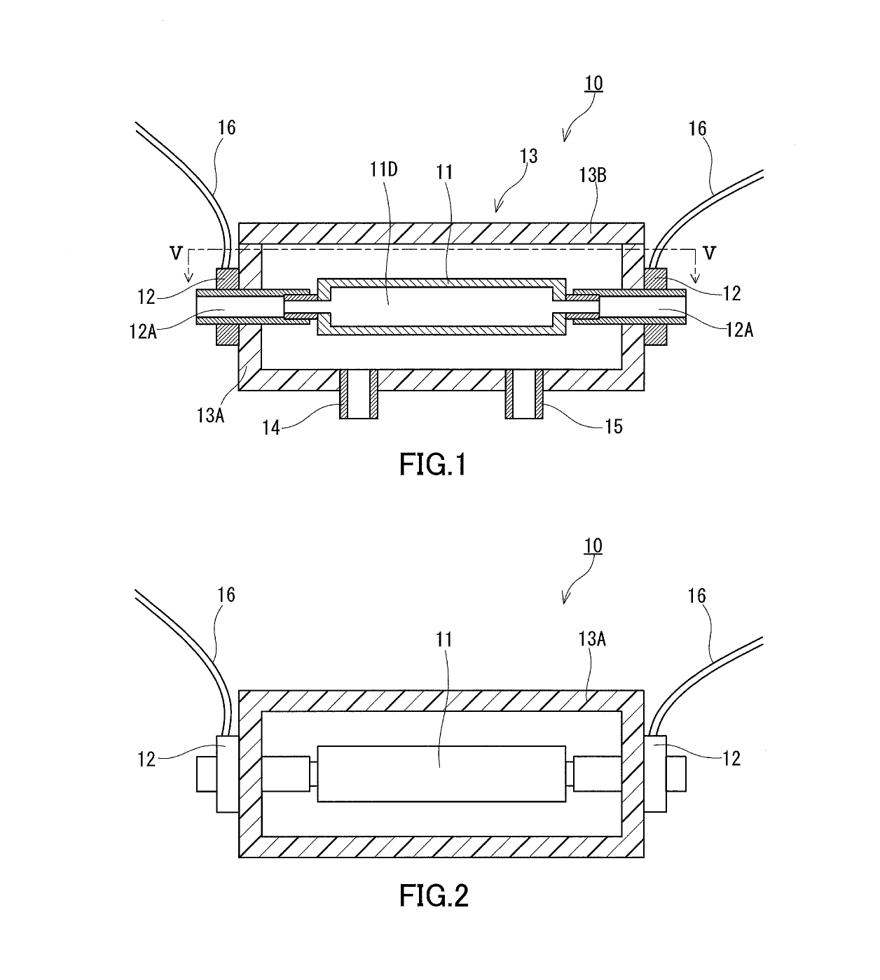

First, a thermoelectric power generation device 10 of the present embodiment is described with reference to FIG. 1 and FIG. 2. The thermoelectric power generation device 10 includes a sealed vessel 13 having an enclosed interior space, a tubular thermoelectric element 11 disposed in the interior space of the vessel 13, a pair of flow path members 12 each connected to the end of the thermoelectric element 11 and penetrating the wall of the vessel 13 and extending to the outside of the vessel 13, and a pair of lead wires 16 connected to the flow path members 12 in the outside of the vessel 13. The ends of the thermoelectric element 11 are each connected to one of the pair of flow path members 12.

A top opening of a vessel body 13A as a bottomed container is covered with a lid 13B to seal the vessel 13 and form an enclosed space therein. An inlet 14 and an outlet 15 are formed in the bottom of the vessel body 13A. The inlet 14 and the outlet 15 are formed, for example, by inserting grooved tube connectors into screw holes formed in the wall of the vessel body 13A. A hose for supplying a first fluid into the vessel 13 is inserted into the tube connector for the inlet 14, and a hose for discharging the first fluid from the vessel 13 is inserted into the tube connector for the outlet 15. The inlet 14 and the outlet 15 may be formed by shaping the wall of the vessel 13 into a shape like a telescopic-joint The inlet 14 and the outlet 15 may be formed by fabricating the wall of the vessel 13 into a shape like a telescopic-joint.

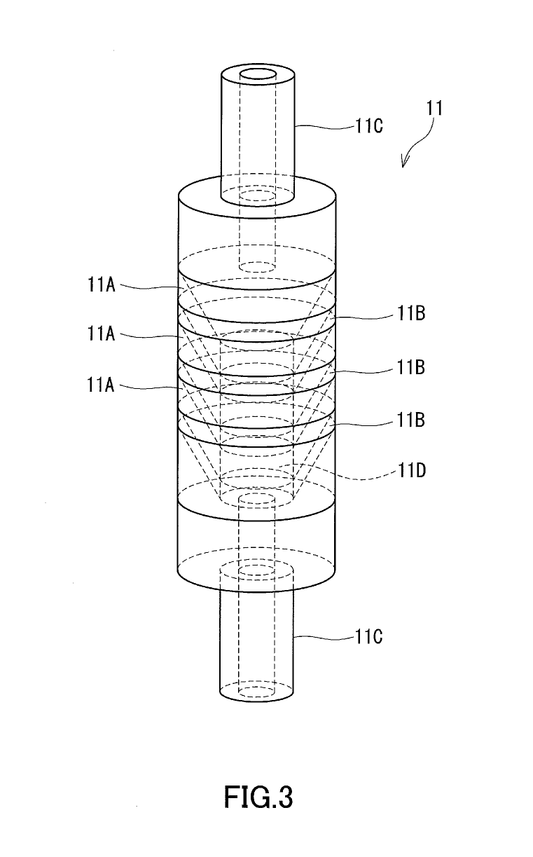

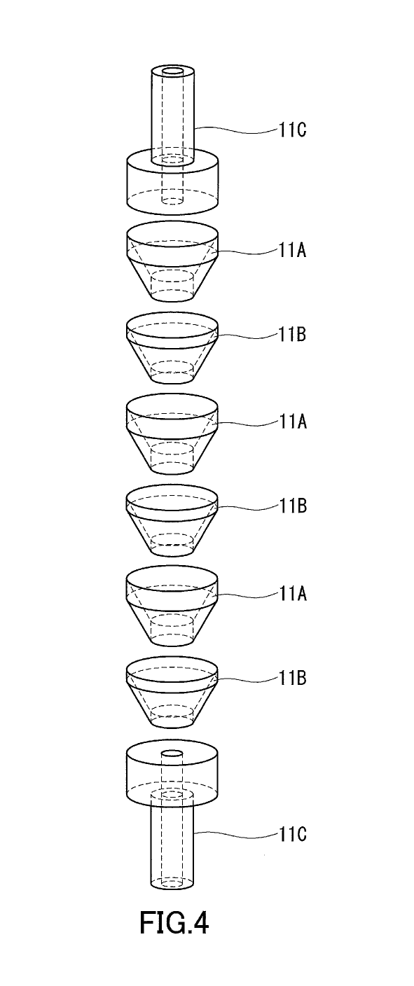

The tubular thermoelectric element 11 is disposed in the interior space of the vessel 13. The thermoelectric element 11 is described with reference to FIG. 3 and FIG. 4. As shown in FIG. 3 and FIG. 4, conical ring-shaped first members 11A each having a through-hole and conical ring-shaped second members 11B each having a through-hole are alternately stacked. In addition, end members 11 C each having a through-hole and composed of two cylindrical portions with different outer diameters are disposed at both ends of the stack of the first members 11A and the second members 11B. The first members 11A, the second members 11B, and the end members 11C are connected one to another with solder paste so as to form the thermoelectric element 11. The through-holes of the first members 11A, the second members 11B, and the end members 11C are connected one to another so as to form a flow-through path 11D of the thermoelectric element 11. In FIG. 3 and FIG. 4, three first members 11A and three second members 11B are alternately stacked, but an arbitrary number of first members 11A and second members 11B may be stacked.

The first member 11A is made of a metal, and the metal is, for example, nickel, cobalt, copper, aluminum, silver, gold, or an alloy thereof. The second member 11B is made of a thermoelectric material, and the thermoelectric material is, for example Bi, Bi₂Te₃, Bi_{0.5}Sb_{1.5}Te₃, or PbTe. Bi₂Te₃ may contain Sb or Se. The end member 11C is made of a metal, and the metal is, for example, copper.

When a temperature difference occurs between the inner peripheral surface and the outer peripheral surface of the thermoelectric element 11, an electromotive force is generated in the axial direction of the thermoelectric element 11 by the Seebeck effect.

Returning to FIG. 1, the description of the thermoelectric power generation device 10 continues. A pair of opposite side walls of the vessel body 13A are each provided with the flow path member 12 penetrating the side wall. The flow path member 12 extends from the side wall of the vessel 13 to the outside of the vessel 13. The flow path member 12 includes a communication flow path 12A extending from one end of the flow path member 12 to the other end thereof. One end of the flow path member 12 is connected to the end of the thermoelectric element 11 so that the flow-through path 11D communicates with the outside of the vessel 13 through the communication flow path 12A. In the pair of flow path members 12, one flow path member 12 is connected to one end of the thermoelectric element 11, and the other flow path member 12 is connected to the other end of the thermoelectric element 11.

In other words, the pair of flow path member 12 support both ends of the thermoelectric element 11 so that the thermoelectric element 11 is disposed apart from the inner peripheral surface of the vessel 13. The thermoelectric element 11 and the flow path member 12 can be connected in various ways. For example, they can be screw-cut to engage them, or they can be connected together with a nut and a ferrule.

The flow path member 12 can be provided in the side wall of the vessel 13 in various ways. For example, a tubular joint having a screw-cut outer periphery can be inserted into a screw hole formed in the side wall of the vessel 13, or a union joint serving as the flow path member 12 can be inserted into a drilled hole formed in the side wall of the vessel 13.

The supply hose for supplying a second fluid to be described later to the flow-through path 11D is inserted into a portion of one of the flow path members 12 projecting outwardly from the vessel 13. The discharge hose for discharging the second fluid flowing in the flow-through path 11D to the outside of the vessel 13 is inserted into a portion of the other flow path member 12 projecting outwardly from the vessel 13.

The flow path member 12 includes a conductive portion extending from the connecting portion with the end of the thermoelectric element 11 to the outside of the vessel 13. A lead wire 16 is connected to the conductive portion in the outside of the vessel 13. In the present embodiment, the flow path member 12 is made of a conductive material, and the entire flow path member 12 corresponds to the conductive portion. Examples of the conductive material as the material of the flow path members 12 include metals such as copper, aluminum, brass, and stainless steel. The lead wire 16 can be connected to the conductive portion of the flow path member 12 in various ways. For example, the lead wire 16 can be pressure-bonded to the conductive portion using a piece of indium, or the lead wire 16 connected to a crimp contact can be screwed into a screw hole formed in the flow path member 12. The conductive portion of the flow path member 12 may include a substrate made of an insulating material and a conductive layer such as a metal layer covering the substrate. This is advantageous in reducing the weight of the flow path member 12. The conductive layer need not be formed on the entire surface of the substrate. The conductive layer may be formed on the substrate so as to cover a connecting portion between the conductive portion of the flow path member 12 and the thermoelectric element 11 and a connecting portion between the conductive portion and the lead wire 16 in the outside of the vessel 13. For example, a fluororesin substrate coated with a metal layer may be used. The electrical resistance of the conductive portion is desirably 100 mΩ or less.

In this description, the term “conductive material” refers to a material having an electrical conductivity of 10⁶ S/m or more at 20° C., and the term “insulating material” refers to a material having an electrical conductivity of less than 10⁻⁶ S/m at 20° C.

The flow path member 12 and the vessel 13 are electrically insulated from each other. In the present embodiment, the vessel 13 is formed of, for example, an insulating material, such as an acrylic resin or a fluororesin, and is electrically insulated from the flow path member 12 formed of a conductive material.

Next, an electric power generation method using the thermoelectric power generation device 10 is described with reference to FIG. 1.

First, the thermoelectric element 11 is placed in the vessel body 13A, and the lid 13B is fixed to the vessel body 13A with screws or the like to seal the vessel 13 to form an enclosed interior space. Thus, the thermoelectric power generation device 10 is prepared. In this state, the first fluid is supplied into the enclosed space of the vessel 13, and the second fluid having a different temperature from the first fluid is supplied to the flow-through path 11D. The first fluid is supplied into the vessel 13 through the inlet 14. The second fluid having a different temperature from the first fluid is supplied to the flow-through path 11D of the thermoelectric element 11 through one of the flow path members 12, and flows through the flow-through path 11D toward the other flow path member 12. The outer peripheral surface of the thermoelectric element 11 comes into contact with the first fluid, and the inner peripheral surface thereof forming the flow-through path 11D comes into contact with the second fluid having a temperature different from that of the first fluid. As a result, a temperature difference occurs between the outer peripheral surface of the thermoelectric element 11 and the inner peripheral surface thereof forming the flow-through path 11D. This temperature difference causes an electromotive force to be generated in the axial direction of the thermoelectric element 11 by the Seebeck effect. Electric power derived from the electromotive force generated in the thermoelectric element 11 is transmitted to the outside of the thermoelectric element 11 through the conductive portions of the flow path members 12 and the lead wires.

The first fluid in the vessel 13 is discharged to the outside of the vessel 13 through the outlet 15. The second fluid flowing in the flow-through path 11D of the thermoelectric element 11 is discharged to the outside of the flow-through path 11D through the other flow path member 12. The first fluid and the second fluid are continuously supplied into the vessel 13 and the flow-through path 11D, respectively. As a result, a temperature difference occurs continuously between the inner peripheral surface of the thermoelectric element 11 and the outer peripheral surface thereof, and thereby the thermoelectric element 11 continuously generates electric power.

As the first fluid and the second fluid, for example, a liquid such as water, oil, or alcohol, or a gas such as water vapor can be used. The temperature of the first fluid may be higher or lower than that of the second fluid. The amount of electric power generated in the thermoelectric power generation device 10 increases as the temperature difference between the first fluid and the second fluid increases. Therefore, it is desirable that the temperature difference between the first fluid and the second fluid be sufficiently large.

### Second Embodiment

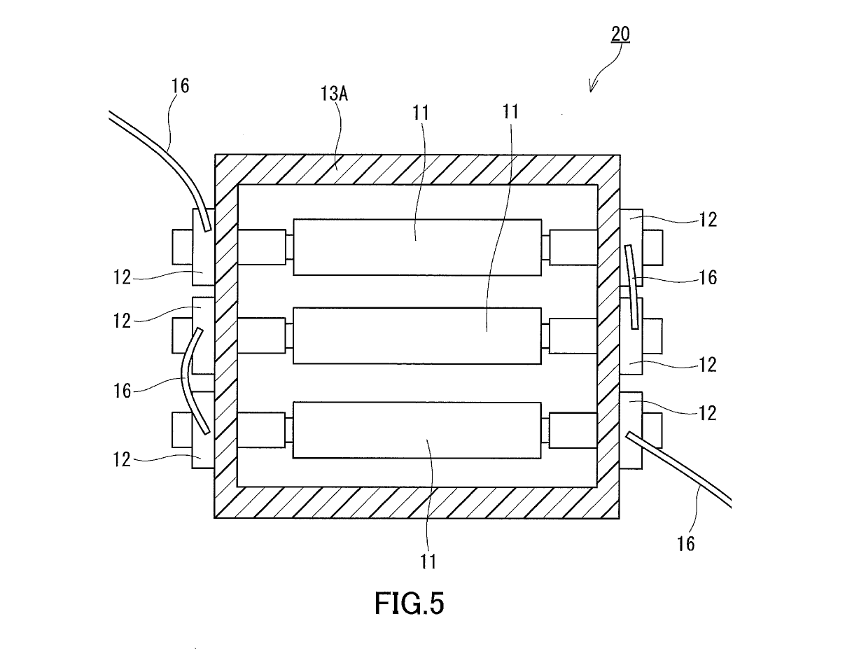

A thermoelectric power generation device 20 according to the second embodiment is described with reference to FIG. 5. The thermoelectric power generation device 20 is configured in the same manner as the thermoelectric power generation device 10 of the first embodiment, unless otherwise described below. Therefore, the same components as those of the thermoelectric power generation device 10 of the first embodiment are described using the same reference numerals.

In the thermoelectric power generation device 20, three thermoelectric elements 11 are disposed in the vessel 13. Both ends of each of the three thermoelectric elements 11 are supported by a pair of flow path members 12. Herein, the thermoelectric elements 11, the flow path elements 12, and the vessel 13 are configured in the same manner as those of the first embodiment.

The lead wires 16 are connected to the conductive portions of the pairs of flow path members 12 in the outside of the vessel 13 so as to connect the three thermoelectric elements 11 in series. Specifically, two of the four lead wires 16 each connect the three thermoelectric elements 11 that are connected in series to an external circuit, and the other two lead wires 16 each connect the conductive portions of two thermoelectric elements 11 disposed adjacent to each other.

The series connection of the plurality of thermoelectric elements 11 makes it possible to increase the amount of electric power generated in the entire thermoelectric power generation device.

### Other Embodiments

The present disclosure can be implemented in various ways. For example, in the first embodiment, the vessel 13 may be made of a conductive material such as a metal. In this case, the contact portions between the flow path members 12 and the vessel 13 can be coated in advance with an insulating layer such as Al₂O₃ or SiO₂. Such an insulating layer can be formed by a known deposition technique such as sputtering or PLD (Pulse Laser Deposition). Such an insulating layer may be provided on either the flow path members 12 or the vessel 13, and it may be provided on both the flow path members 12 and the vessel 13.

In the above-described embodiment, the inlet 14 and the outlet 15 for the first fluid are formed in the bottom of the vessel 13, but they may be formed in the side wall of the vessel 13.

### EXAMPLES

Next, the present disclosure will be described in more detail by way of Examples. The present disclosure is not limited to the following examples.

### Example 1

### Production of Thermoelectric Element

Conical rings made of Ni and conical rings made of Bi₂Te₃ as shown in FIG. 4 were produced by casting. The Ni conical rings were produced to have a maximum outer diameter of 14 mm, a minimum inner diameter of 10 mm, and a height of 4 mm. The Bi₂Te₃ conical rings were produced to have a maximum outer diameter of 14 mm, a minimum inner diameter of 10 mm, and a height of 3.2 mm. The Ni conical rings and the Bi₂Te₃ conical rings were produced so that when the Ni conical rings and the Bi₂Te₃ conical rings are stacked, the adjacent surfaces of the stacked conical rings were inclined at an angle of 30° with respect to the stacking direction of these conical rings.

End members made of copper were produced by machining. These copper end members each having two end portions were produced by machining so that one end portion had a cylindrical shape with an outer diameter of 6 mm and a length of 17 mm, the other end portion had a cylindrical shape with an outer diameter of 14 mm and a length of 5 mm, and the end member had a total length of 22 mm. A through-hole with a diameter of 4 mm was formed in the center of the end member.

The Ni conical rings and the Bi₂Te₃ conical rings were alternately put on an aluminum round bar with an outer diameter of 4 mm so as to stack the Ni conical rings and the Bi₂Te₃ conical rings. The above-mentioned end members were placed at both ends of this stack of the Ni conical rings and the Bi₂Te₃ conical rings. Sn—Bi solder paste was applied between the adjacent Ni conical rings, Bi₂Te₃ conical rings, and end members. The stack of the Ni conical rings, the Bi₂Te₃ conical rings, and the end members thus assembled was placed in an electric furnace and heated at 180° C. for 60 minutes. Then, the stack was cooled to room temperature and taken out of the electric furnace, and the aluminum round bar was removed from the stack. Thus, a tubular thermoelectric element with an outer diameter of 14 mm, an inner diameter of 10 mm, and a length of 1100 mm was obtained. The electrical resistance of this tubular thermoelectric element was 4.5 mΩ.

As the flow path members, union joints made of SUS316 (Swagelok) were used. The electrical resistance of the union joints was about 0.25 mΩ.

An open-top acrylic water tank with a width of 30 mm, a length of 150 mm, and a height of 20 mm was prepared. Two through-holes were formed in the opposite side walls of the water tank to insert the union joints therethrough, and two screw holes were formed in the bottom wall of the water tank to insert tube connectors thereinto. M3 screw holes were formed at 30 mm intervals in the upper edges of the open-top water tank. The thickness of the water tank was 10 mm. An acrylic lid with a width of 30 mm, a length of 150 mm, and a height of 5 mm was also prepared. Through-holes are formed at 30 mm intervals along the periphery of the lid.

Next, both ends of the tubular thermoelectric element thus produced were connected to the pair of union joints in the water tank. While the union joints were inserted through the through-holes for the union joints in the water tank from outside thereof, silicone rubber gaskets were placed between the union joints and the walls of the water tank. Silicone rubber hoses were connected to the pair of union joints projecting outwardly from the water tank. The silicone rubber hose connected to one of the union joints was connected to a hot water inlet of a hot water circulation apparatus, and the silicon rubber hose connected to the other union joint was connected to a hot water outlet of the hot water circulation apparatus.

SUS tube connectors (Swagelok) were connected to the two screw holes formed in the bottom wall of the water tank, and two silicone rubber hoses with a diameter of 6 mm were connected to these SUS tube connectors. One of the silicone rubber hoses was connected to a cold water inlet of a cold water circulation apparatus. The other silicone rubber hose was connected to a cold water outlet of the cold water circulation apparatus.

Next, the lid was screwed to the water tank via silicone rubber gaskets to seal the water tank. Finally, lead wires were pressure-bonded to the union joints projecting outwardly from the water tank using a piece of indium. Thus, a thermoelectric power generation device was produced. The electrical resistance of the union joints and that of the entire tubular thermoelectric element were both 5.5 mΩ when they were measured using the lead wires connected to the union joints.

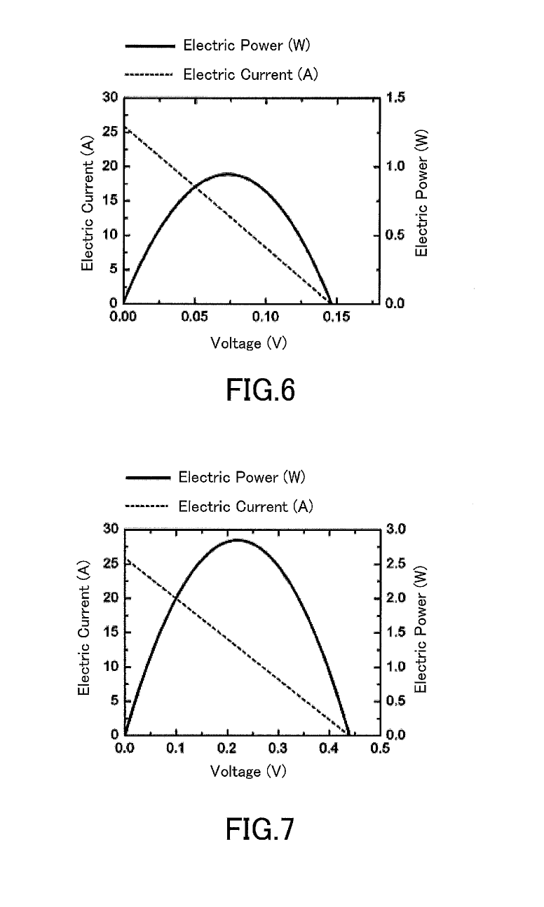

The hot water circulation apparatus was used to cause water of 80° C. to flow into the tubular thermoelectric element at a flow rate of 5 L/min, and the cold water circulation apparatus was used to cause water of 10° C. to flow into the water tank at a flow rate of 7 L/min. Thus, electric power generation was performed. FIG. 6 shows the electric power generation performance of the thermoelectric power generation device according to Example 1. The open circuit voltage measured between the lead wires was 150 mV. When a load was connected and the electric power generation performance was measured, electric power of 0.98 W was generated under the above-mentioned conditions.

### Example 2

Three tubular thermoelectric elements were produced in the same manner as in Example 1. The electrical resistances of the tubular thermoelectric elements were all 4.5 mΩ.

As the flow path members, union joints made of SUS316 (Swagelok) were used. The electrical resistance of the union joints was about 0.25 mΩ.

An open-top acrylic water tank with a width of 130 mm, a length of 150 mm, and a height of 20 mm was prepared. Three through-holes were formed in each of the opposite side walls of the water tank to insert the union joints therethrough. Thus, six through-holes in total were formed. Six screw holes were formed in the bottom wall of the water tank to connect tube connectors thereto. M3 screw holes were formed at 30 mm intervals in the upper edges of the open-top water tank. The thickness of the wall of the water tank was 10 mm. An acrylic lid with a width of 130 mm, a length of 150 mm, and a height of 5 mm was also prepared. Through-holes were formed at 30 mm intervals along the periphery of the lid.

Next, both ends of each of the above-described three tubular thermoelectric elements were connected to a pair of union joints in the water tank. While the union joints was inserted through the through-holes for the union joints in the water tank from outside thereof, silicone rubber gaskets were placed between the union joints and the walls of the water tank. Silicone rubber hoses were respectively connected to the six union joints projecting outwardly from the water tank. The three silicone rubber hoses connected to the three union joints provided in one of the side walls were integrated into one tube with piping parts, and the tube was connected to a hot water inlet of a hot water circulation apparatus. The three silicone rubber hoses connected to the three union joints provided in the other side wall were also integrated into one tube with piping parts, and the tube was connected to a hot water outlet of the hot water circulation apparatus.

SUS tube connectors (Swagelok) were connected to the six screw holes formed in the bottom wall of the water tank, and six silicone rubber hoses with a diameter of 6 mm were connected to these SUS tube connectors. The three silicone rubber hoses were integrated into one tube with piping parts, and the tube was connected to a cold water inlet of a cold water circulation apparatus. The other three silicone rubber hoses were also integrated into one tube with piping parts, and the tube was connected to a cold water outlet of the cold water circulation apparatus.

Next, the lid was screwed to the water tank via silicone rubber gaskets to seal the water tank. Finally, lead wires were pressure-bonded to the union joints projecting outwardly from the water tank using a piece of indium so as to electrically connect the three tubular thermoelectric elements in series. Thus, a thermoelectric power generation device according to Example 2 was produced. The electrical resistance of the entire thermoelectric power generation device was 17 mΩ when it was measured using the lead wires connected to the union joints.

The hot water circulation apparatus was used to cause water of 80° C. to flow into each of the tubular thermoelectric elements at a flow rate of 5 L/min, and the cold water circulation apparatus was used to cause water of 10° C. to flow into the water tank at a flow rate of 7 L/min. Thus, electric power generation was performed. FIG. 7 shows the electric power generation performance of the thermoelectric power generation device according to Example 2. The open circuit voltage measured between the lead wires was 440 mV. When a load was connected and the electric power generation performance was measured, electric power of 2.8 W was generated under the above-mentioned conditions.

### Comparative Example

A tubular thermoelectric element was produced in the same manner as in Example 1. The resistance of the tubular thermoelectric element thus produced was 4.5 mΩ. An open-top acrylic water tank with a width of 300 mm, a length of 300 mm, and a height of 300 mm was prepared.

Silicone rubber tubes were connected directly to both ends of the tubular thermoelectric element thus produced. One of the silicone rubber tubes was connected to a hot water inlet of a hot water circulation apparatus. The other silicone rubber tube was connected to a hot water outlet of the hot water circulation apparatus.

Silicone rubber tubes connected to a cold water inlet and a cold water outlet of a cold water circulation apparatus were put into the water tank, and the water tank was filled with cold water to a height of 20 cm.

Lead wires were pressure-bonded to both ends of the tubular thermoelectric element using a piece of indium. The tubular thermoelectric element in this state was submerged in the water tank. Thus, the thermoelectric power generation device according to Comparative Example was obtained. In the thermoelectric power generation device according to Comparative Example, the top of the water tank was kept open.

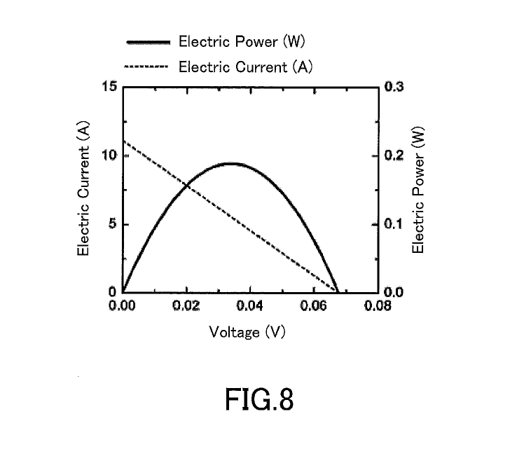

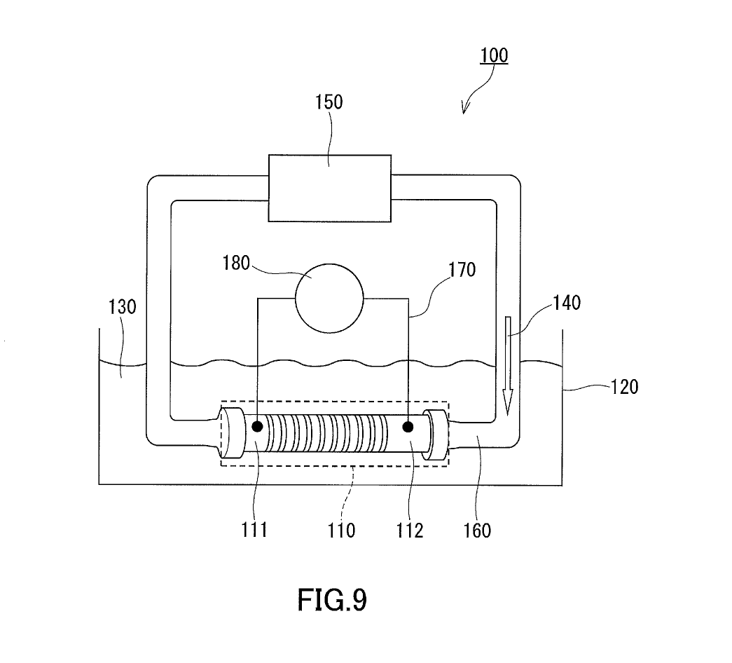

The hot water circulation apparatus was used to cause water of 80° C. to flow into the tubular thermoelectric element at a flow rate of 5 L/min, and the cold water circulation apparatus was used to cause water of 10° C. to flow into the water tank at a flow rate of 7 L/min. Thus, electric power generation was performed. FIG. 8 shows the electric power generation performance of the thermoelectric power generation device according to Comparative Example. The open circuit voltage measured between the lead wires was 65 mV. When a load was connected and the electric power generation performance was measured, electric power of 0.2 W was generated under the above-mentioned conditions.

The amount of electric power generated in the thermoelectric power generation device of Example 1 was about five times the amount of electric power generated in the thermoelectric power generation device of Comparative Example. Presumably, this is because in the water tank closed with the lid, the flow velocity of cold water in the vicinity of the tubular thermoelectric element was increased and thus the tubular thermoelectric element was cooled efficiently. As shown by the amount of electric power generated in the thermoelectric power generation device of Example 2, it was confirmed that a series connection of a plurality of tubular thermoelectric elements increased the amount of electric power generated in the resulting thermoelectric power generation device.

The present disclosure may be embodied in other forms without departing from the spirit or essential characteristics thereof. The embodiments disclosed in this specification are to be considered in all respects as illustrative and not limiting. The scope of the present disclosure is indicated by the appended claims rather than by the foregoing description, and all changes which come within the meaning and range of equivalency of the claims are intended to be embraced therein.

### INDUSTRIAL APPLICABILITY

The thermoelectric power generation device of the present disclosure can be applied to electric power generation using waste heat or heat from hot springs.

What is claimed is:

1. A thermoelectric power generation device, comprising:
a vessel having an inlet through which a first fluid is introduced into the vessel and an outlet through which the first fluid is discharged from the vessel, the vessel being sealed to form an enclosed interior space therein;
a tubular thermoelectric element having a flow-through path through which a second fluid having a temperature different from that of the first fluid flows, the thermoelectric element being disposed in the interior space of the vessel;
a pair of flow path members each having a communication flow path therein, the pair of flow path members being connected to ends of the thermoelectric element so as to allow the flow-through path to communicate with an outside of the vessel through the communication flow paths; and
lead wires,
wherein
the pair of flow path members each penetrate a wall of the vessel while being electrically insulated from the vessel and each have a conductive portion extending from a connecting portion between the flow path member and the thermoelectric element to the outside of the vessel, and
the lead wires are each connected to the conductive portion in the outside of the vessel.

2. The thermoelectric power generation device according to claim 1, wherein the flow path members are formed of a conductive material, and the vessel is formed of an insulating material.

3. The thermoelectric power generation device according to claim 1, wherein the conductive portion includes: a substrate made of an insulating material; and a conductive layer covering an outer surface of the substrate, and the vessel is formed of an insulating material.

4. The thermoelectric power generation device according to claim 1, wherein the conductive portion has an electrical resistance of 100 mΩ or less.

5. A thermoelectric power generation device comprising:
a vessel having an inlet through which a first fluid is introduced into the vessel and an outlet through which the first fluid is discharged from the vessel, the vessel being sealed to form an enclosed interior space therein;
a plurality of tubular thermoelectric elements each having a flow-through path through which a second fluid having a temperature different from that of the first fluid flows, the thermoelectric elements being disposed in the interior space of the vessel;
pairs of flow path members each having a communication flow path therein, each of the pairs of flow path members corresponding to one of the thermoelectric elements and being connected to ends of the thermoelectric element so as to allow the flow-through path to communicate with an outside of the vessel through the communication flow paths; and
lead wires,
wherein
the flow path members each penetrate a wall of the vessel while being electrically insulated from the vessel and each have a conductive portion extending from a connecting portion between the flow path member and the thermoelectric element to the outside of the vessel,
the lead wires are connected to the conductive portions in the outside of the vessel, and
the thermoelectric elements are connected in series through the lead wires and the conductive portions.

6. A method for generating electric power, comprising the steps of:
preparing the thermoelectric power generation device according to claim 1;
introducing the first fluid into the vessel through the inlet and discharging the first fluid from the vessel through the outlet;
causing the second fluid to flow in the flow-through path through the flow path members; and
transmitting electric power generated in the thermoelectric element to the outside of the vessel through the flow path members and the lead wires.
